(19) United States
(12) Patent Application Publication
(10) Pub. No.: US 2025/0138741 A1
(43) Pub. Date: May 1, 2025

(54) SEMICONDUCTOR DEVICE AND WRITING METHOD

(71) Applicant: Renesas Electronics Corporation, Tokyo (JP)

(72) Inventor: Kouichi SAKAGUCHI, Tokyo (JP)

(21) Appl. No.: 18/921,336

(22) Filed: Oct. 21, 2024

(30) Foreign Application Priority Data
Oct. 27, 2023 (JP) 2023-184433

(51) Int. Cl. G06F 3/06

(52) U.S. Cl. CPC G06F 3/0644; G06F 3/061; G06F 3/0673

(57) ABSTRACT

Access time from a CPU to a register can be reduced while complication of software is prevented. A semiconductor device includes: a decoder circuit determining a write-source process; a write-enable setting storage circuit storing a write-enable setting that indicates a processor enabled to execute writing into each bit of a write-destination register; a masking/merging circuit generating a value to be written back into the write-destination register on the basis of the write-enable setting and the write-source processor; and a write-back circuit writing back the value to be written back into the write-destination register.

### CROSS-REFERENCE TO RELATED APPLICATION

The present application claims priority to Japanese Patent Application No. 2023-184433 filed on Oct. 27, 2023, the disclosure of which is incorporated herein by reference.

### BACKGROUND

The present invention relates to a semiconductor device that executes data writing and relates to a writing method.

In recent years, it has been demanded to mount a plurality of CPUs (Central Processing Units) on a semiconductor device such as an in-vehicle micro computer to successively execute a safety-related function even if any failure occurs. The safety-related function includes a function of avoiding a series of the failures at the time of access from the plurality of CPUs to a shared resource register. In the shared resource register mounted on the in-vehicle micro computer, one register may include a bit portion enabled to be accessed from the plurality of CPUs.

There is disclosed technique listed below.
[Patent Document 1] International Patent Publication No. 2010/029682

In a related art, only the enabled bit portion can be rewritten by a read-modify-write method. For example, the Patent Document 1 discloses a technique related to an information processor executing the read-modify-write method.

However, the execution of the read-modify-write method needs an arbitration processing of stopping access from a CPU different from the CPU accessing to the register and a plurality of access processings and arithmetic processings based on the read-modify-write method. Therefore, the method has problems that are complication of software and increase in access time from the CPU to the register.

The complication of the software and the increase in the access time from the CPU become causes of increase in the manhours for the software development and decrease in a performance of the in-vehicle micro computer. Therefore, the needs for a function and a system of avoiding a series of failures based on hardware have increased. Such function and system are called FFI (Freedom From Interface), and are required by ISO26262.

### SUMMARY

As described above, it is desirable to reduce the access time from the CPU to the register while preventing the complication of the software.

Other objects and novel characteristics will be apparent from the description of the present specification and the accompanying drawings.

A semiconductor device according to one embodiment includes: a decoder circuit determining a write-source processor; a write-enable setting storage circuit storing a write-enable setting that indicates a processor enabled to execute writing into each bit of a write-destination register; a masking/merging circuit generating a value to be written back into the write-destination register on the basis of the write-enable setting and the write-source processor; and a write-back circuit writing back the value to be written back into the write-destination register.

A write method according to one embodiment includes: a step of determining a write-source processor; a step of generating a value to be written back into a write-destination register on the basis of the write-source processor and a write-enable setting that indicates a processor enabled to execute writing into each bit of the write-destination register; and a step of writing back the value to be written back into the write-destination register.

According to the embodiment, access time from the CPU to the register can be reduced while the complication of the software is prevented.

### BRIEF DESCRIPTIONS OF THE DRAWINGS

FIG. 1 is a schematic circuit diagram showing a configuration of a semiconductor device according to a first embodiment.

FIG. 2 is a schematic circuit diagram showing a configuration of a decoder circuit according to the first embodiment.

FIG. 3 is a schematic circuit diagram showing a write-enable setting circuit according to the first embodiment.

FIG. 4 is a schematic circuit diagram showing a configuration of a masking/merging circuit according to the first embodiment.

FIG. 5 is a time chart showing an operation of the decoder circuit according to the first embodiment.

FIG. 6 is a time chart showing an operation of the masking/merging circuit according to the first embodiment.

FIG. 7 is a time chart showing an operation of the write-back circuit according to the first embodiment.

FIG. 8 is a diagram for explaining a configuration of a semiconductor device according to a second embodiment.

FIG. 9 is a schematic circuit diagram showing a configuration of a write-back circuit according to the second embodiment.

FIG. 10 is a time chart for explaining an operation of the write-back circuit according to the second embodiment.

### DETAILED DESCRIPTION

For clear explanation, the following description and drawings are appropriately omitted and simplified. Each of elements illustrated in the drawings, respectively, as functional blocks that execute various types of processing, can be configured of a CPU, a memory, or another circuit in a hardware manner, or is achieved by execution of a program or the like loaded in the memory in a software manner. Therefore, it would be understood by those skilled in the art that the functional blocks can be achieved in various forms by hardware, software operating on the hardware, or their combination, and are not limited to any one of the forms. In each drawing, the same elements are respectively denoted by the same reference symbols, and description thereof is not repeated as needed.

The program includes a command group (or software code) for causing a computer to execute one or more functions explained in embodiments when being loaded into the computer. The program may be stored in a non-transitory computer readable medium or a tangible storage medium. The computer readable media or tangible storage media may include, for example, Random Access Memory (RAM), Read Only Memory (ROM), flash memory, Solid State Drive (SSD), other memory techniques, CD-ROM, Digital Versatile Disc (DVD), Blu-ray (registered trademark) disc, other optical disc storage, magnetic cassette, magnetic tape, magnetic disk storage, and other magnetic storage device, but are not limited thereto. The program may be transmitted on a transitory computer readable medium or communication medium. The transitory computer readable media or communication media include, for example, electrical, optical, acoustic, and other-form propagation signals, but are not limited thereto.

### First Embodiment

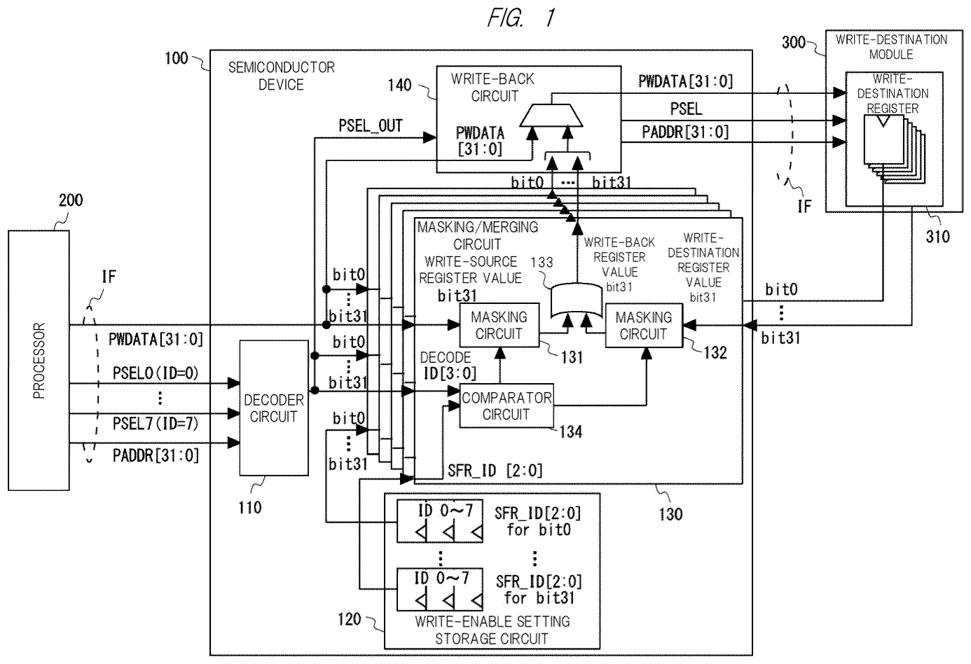

FIG. 1 is a schematic circuit diagram showing a configuration of a semiconductor device 100 according to a first embodiment. PWDATA[31:0], bus slave selecting signals PSEL0 to PSEL7 and PADDR[31:0] are input from a write-source processor 200 to the semiconductor device 100 through an APB (Advanced Peripheral Bus) bus interface IF. The PWDATA[31:0] is also referred to as write data. The PADDR[31:0] is also referred to as bus address. The bus slave selecting signals PSEL0 to PSEL7 correspond to ID0 to ID7 of the write-source processors. Note that the number of IDs may be two or more and 6 or less, or 8 or more. Then, the semiconductor device 100 executes the writing into a write-destination register 310 of a write-destination module 300 through the APB bus interface IF.

The semiconductor device 100 includes a decoder circuit 110, a write-enable setting storage circuit 120, a masking/merging circuit 130, and a write-back circuit 140.

As an input, the decoder circuit 110 receives the bus slave selecting signals PSEL0 to PSEL7 and the PADDR[31:0]. The bus slave selecting signal PSEL indicates a write-source processor 200. The decoder circuit 110 identifies the write-source processor 200.

The decoder circuit 110 stores information (also referred to as MASK_CON) as to whether a masking process is to be executed on each bit of the write-destination register 310. For example, if the masking process is not executed on a bit, all processors may be enabled to write data into the bit. If the masking process is executed on a bit, a specific processor may be enabled to write data into the bit.

The decoder circuit 110 generates a decode ID (also referred to as decode signal) based on the MASK_CON and the bus slave selecting signals PSEL0 to PSEL7, and outputs the decode ID to the masking/merging circuit 130.

Also, the decoder circuit 110 outputs PSEL_OUT based on the PSEL0 to PSEL7, to the write-back circuit 140. Note that a more detailed configuration of the decoder circuit 110 will be described later.

The write-enable setting storage circuit 120 stores a write-enable setting that indicates a processor enabled to execute the writing into each bit of the write-destination register 310. The write-enable setting storage circuit 120 may include, for example, three flip flops corresponding to each bit. As a result, the ID0 to ID7 of the processors 200 can be expressed. The write-enable setting of each bit is also referred to as SFR_ID[2:0]. Note that a detailed configuration of the write-enable setting storage circuit 120 will be described later.

The masking/merging circuit 130 generates a value to be written back into the write-destination register 310, on the basis of the write-enable setting and the write-source processor 200. Specifically, the masking/merging circuit 130 may generate the value to be written back into the write-destination register 310 for each bit, on the basis of the write-enable setting and the decode ID. The masking/merging circuit 130 includes, for example, a masking circuit 131, a masking circuit 132, an OR circuit 133, and a comparator circuit 134. Each of the masking circuits 131 and 132 is made of, for example, an AND circuit or the like. The masking circuit 131 outputs the data to be written (such as PWDATA[31]) to the OR circuit 133 on the basis of an instruction of the comparator circuit 134. The masking circuit 132 outputs the data already written in a bit (such as bit31) of the write-destination register 310 on the basis of the instruction of the comparator circuit 134. The comparator circuit 134 operates the masking circuits 131 and 132 on the basis of the decode ID and the SFR_ID. Note that a detailed configuration of the masking/merging circuit 130 will be described later.

The write-back circuit 140 writes back the value to be written back for each bit input from the masking/merging circuit 130, into the write-destination register 310. Note that the write-back circuit 140 may include a selector for selecting the PWDATA[31:0] and the value to be written back on the basis of PSEL_OUT. The write-back circuit 140 also outputs the PWDATA[31:0], the PSEL and the PADDR[31:0] to the write-destination module 300.

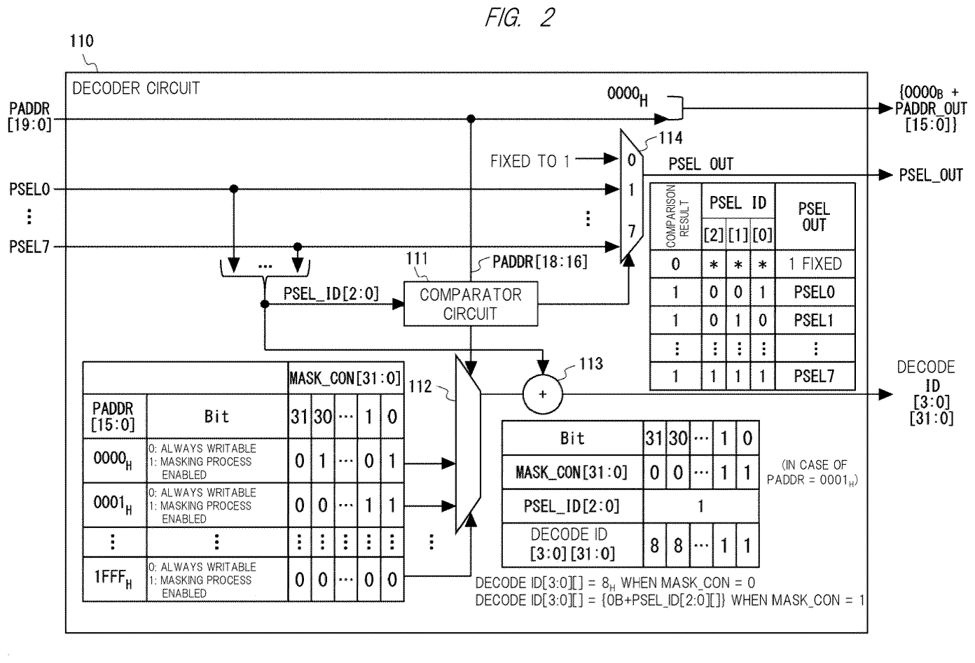

With reference to FIG. 2, the detailed configuration of the decoder circuit 110 will be described. The decoder circuit 110 includes a comparator circuit 111, a selector 112, a signal generator 113 and a selector 114.

The comparator circuit 111 compares PADDR[18:16] included in address bus PADDR[19:0] with PSEL_ID[2:0] that is binarized data of the bus slave selecting signals PSEL0 to PSEL7. The PADDR[18:16] is a bit indicating the write-source processor 200. The comparator circuit 111 outputs a comparison result to the selector 112 and the selector 114.

As an input, for each PADDR[15:0], the selector 112 receives the MASK_CON[31:0] indicating whether the masking process is to be executed on each bit. Note that “H” may be added to a tail end of hexadecimal while “B” may be added to a tail end of binary below.

If the PADDR[15:0] is “0000_{H}”, the MASK_CON[31:0] is expressed as, for example, “01 . . . 01_{B}”. The numeric value “1” indicates that the masking process is valid, and the numeric value “0” indicates an always writable state. If the PADDR[15:0] is “0001_{H}”, the MASK_CON[31:0] is expressed as “00 . . . 11_{B}”. If the PADDR[15:0] is “1FFF_{H}”, the MASK_CON[31:0] is expressed as “00 . . . 000_{B}”. If the signals compared by the comparator circuit 111 are equal, the selector 112 outputs the MASK_CON[31:0] corresponding to the PADDR[15:0], to the signal generator 113.

The signal generator 113 generates a decode ID[3:0][31:0] while using the MASK_CON[31:0] and the PSEL_ID[2:0]. If each bit of the MASK_CON[31:0] is 0, the signal generator 113 sets “the decode ID[3:0][ ] corresponding to this bit=8_{H}”. If each bit of the MASK_CON[31:0] is 1, the signal generator 113 sets “the decode ID[3:0][ ] corresponding to this bit={0_{B}+PSEL_ID[2:0]}”. For example, if the PADDR is “0001_{H}”, the MASK_CON[31:0] is “00 . . . 11_{B}”, and the PSEL_ID[2:0] is “1”. In this case, the decode ID[3:0][31:0] is “88 . . . 11_{H}”.

If each bit of the MASK_CON[31:0] is 0, it can be also said that the signal generator 113 replaces this bit with a predetermined bit (such as 8). If each bit of the MASK_CON[31:0] is 1, it can be also said that the signal generator 113 replaces this bit with the PSEL_ID.

As an input, the selector 114 receives the PSEL0 to PSEL7 and the signal having the output fixed to 1. If the signals compared by the comparator circuit 111 are not equal, the selector 114 outputs 1 as the PSEL_OUT. If the signals compared by the comparator circuit 111 are equal, the selector 114 outputs the PSEL_OUT corresponding to the PSEL0 to PSEL7. For example, if PSEL_ID[2][1][0] is “001”, the selector 114 outputs PSEL0. If PSEL_ID[2][1][0] is “001”, the selector 114 outputs PSEL1. If PSEL_ID[2][1][0] is “111”, the selector 114 outputs PSEL7.

The decoder circuit 110 has a function of outputting {0000_{H}+PADDR[15:0]} based on PADDR[15:0].

The decoder circuit 110 can reduce a probability of occurrence of error writing by using the comparator circuit 111 to compare PSEL_ID[2:0] and PADDR[18:16].

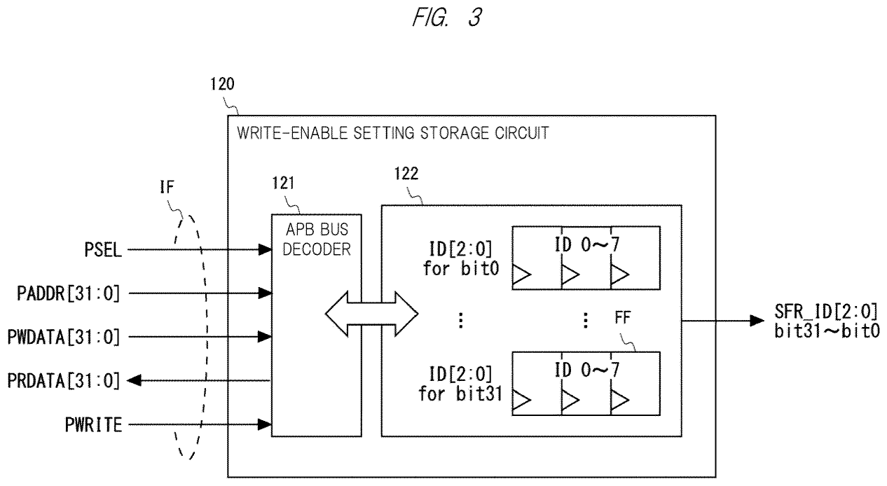

With reference to FIG. 3, the detailed configuration of the write-enable setting storage circuit 120 will be explained. The write-enable setting storage circuit 120 includes an APB bus decoder 121 and a storage 122.

As an input, the APB bus decoder 121 receives the PSEL, the PADDR[31:0], the PWDATA[31:0], and the PWRITE through the APB bus interface IF. The PWRITE is a signal indicating whether to execute the writing. From the APB bus decoder 121, PRDATA[31:0] is output through the APB bus interface IF.

The storage 122 includes three flip flops FF for each bit.

The three flip flops FF store the write-enable setting (also referred to as SRF_ID[2:0]) indicating the ID of the processor enabled to execute the writing into this bit. The storage 122 outputs the SRF_ID[2:0] of each of bit0 to bit31. The write-enable setting can be set through the APB bus decoder 121.

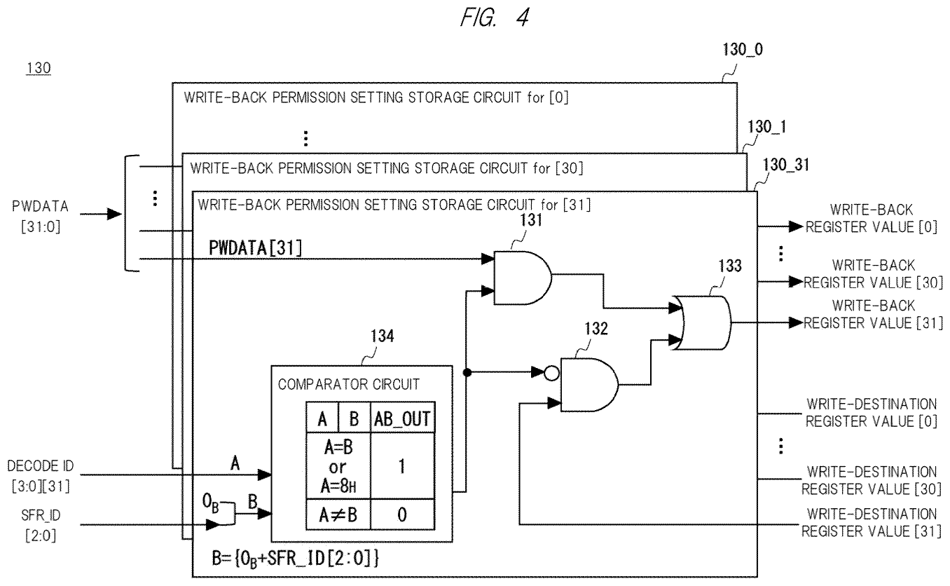

With reference to FIG. 4, the detailed configuration of the masking/merging circuit 130 will be explained. The masking/merging circuit 130 includes a masking/merging circuit 130_0 for the bit0, . . . , a masking/merging circuit 130_30 for the bit30, and a masking/merging circuit 130_31 for the bit31. The masking/merging circuit 130_31 will be specifically explained, and the detailed explanation for the masking/merging circuits 130_0 to 130_30 is omitted.

The masking/merging circuit 130_31 includes an AND circuit 131, an AND circuit 132, an OR circuit 133 and a comparator circuit 134. As an input, the AND circuit 131 receives PWDATA[31] and AB_OUT that is an output of the comparator circuit 134. As an input, the AND circuit 132 receives a register value of the write-destination register 310 and negation of the AB_OUT that is the output of the comparator circuit 134. The OR circuit 133 generates a write-back register value of the write-destination register 310 by taking an OR operation between an output of the AND circuit 131 and an output of the AND circuit 132.

As an input, the comparator circuit 134 receives “A=Decode ID[3:0][31]” and “B={0_{B}+SFR_ID[2:0]}”, and then, outputs “AB_OUT=1” if a condition in which “A=B” or “A=8_{H}” is satisfied. If the condition is not satisfied, specifically if “A≠B” is established, the comparator circuit 134 outputs “AB_OUT=0”.

For example, in a case of “MASK_CON=0” because of no execution of the masking process, “Decode ID[3:0]=8_{H}” is established, and therefore, “AB_OUT=1” is established, and PWDATA is written back. Alternatively, even in a case of “MASK_CON=1”, if PSEL_ID[2:0] and SFR_ID[2:0] are equal to each other, “AB_OUT=1” is established, and PWDATA is written back. If the above-described conditions are not satisfied, “AB_OUT=0” is established, and therefore, the register value of the write-destination register 310 is written back.

The same processing is also executed in the masking/merging circuits 130_0, . . . , and 130_30. As a result, the write-back register value [0], . . . , the write-back register value [30], and the write-back register value [31] are output.

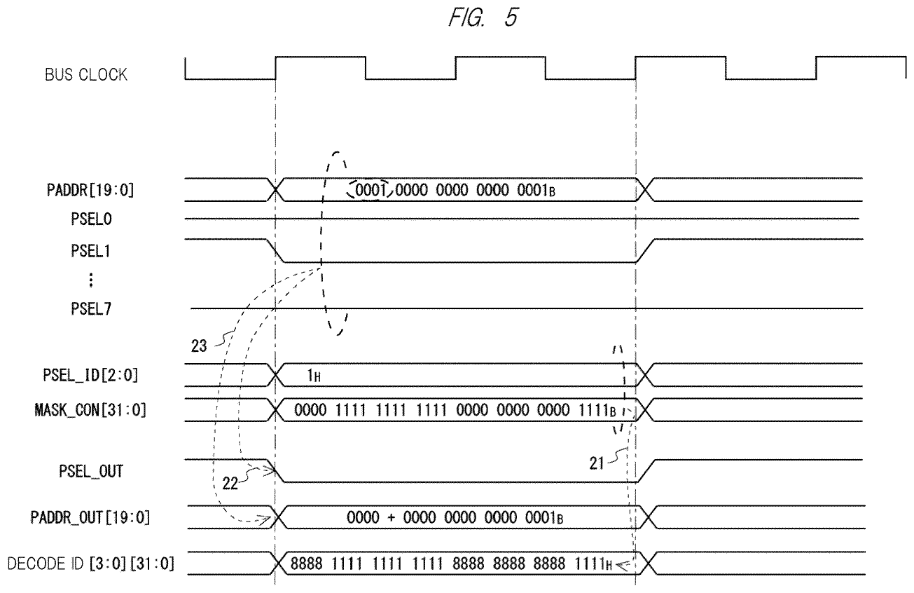

Next, with reference to FIGS. 5 to 7, an operation of the semiconductor device 100 will be explained.

FIG. 5 is a time chart showing an operation of the decoder circuit 110. The decoder circuit 110 determines whether PADDR[19:16] extracted from PADDR[19:0] that is an address accessed from a user is equal to PSEL_ID[2:0] indicating PSEL0 to PSEL7. For example, if the PADDR[19:16] is “0001_{B}” while the PSEL_ID[2:0] is 1_{H}, it may be determined that the PADDR[19:16] is equal to the PSEL_ID[2:0]. Based on this, the decoder circuit 110 determines whether this access is the user's intended access.

The decoder circuit 110 selects information as to whether the masking process is to be executed on each bit of the write-destination register 310, based on PADDR[15:0] indicating the address of the write-destination register 310, and outputs the information as MASK_CON[31:0]. As illustrated with a dotted arrow 21, the decoder circuit 110 replaces “1” included in MASK_CON[31:0] with PSEL_ID[2:0] and replaces “0” included in MASK_CON[31:0] with “8”, and outputs resultant data as the decode ID[3:0][31:0]. As illustrated with a dotted arrow 22, the decoder circuit 110 outputs PSERL_OUT corresponding to PSEL0 to PSEL7. Further, as illustrated with a dotted arrow 23, the decoder circuit 110 outputs “0000_{B}+PADDR[15:0]” as PADDR_OUT[19:0].

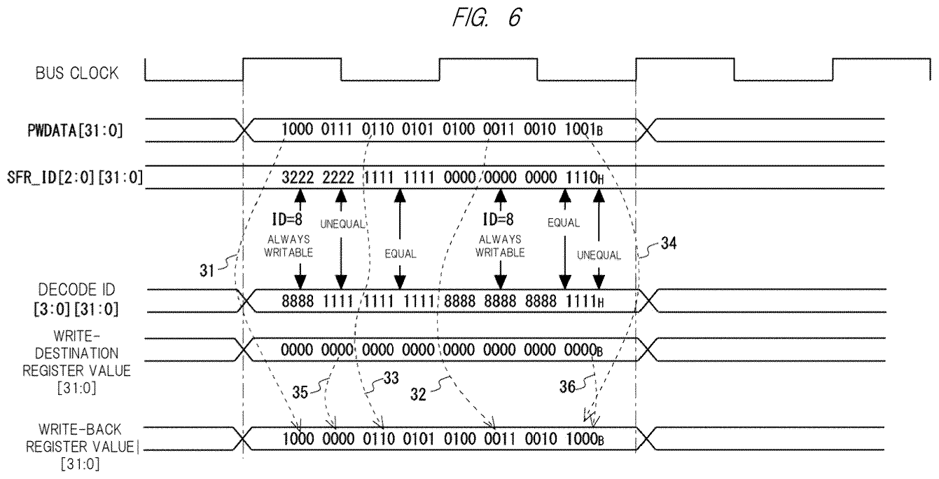

FIG. 6 is a time chart showing an operation of the masking/merging circuit 130. The masking/merging circuit 130 determines for each bit whether a condition in which the decode ID[3:0] is 8 or in which the decode ID[3:0] is equal to SFR_ID[2:0] is satisfied. Into the write-back register value of the bit satisfying this condition, the masking/merging circuit 130 writes PWDATA of this bit.

For example, first to fourth bits from the left of the decode ID[3:0][31:0] are “8888_{H}”, and therefore, the PWDATA and the write-back register value are equal to each other as illustrated with the arrow 31. Because of the same reason, the PWDATA “0011_{B}” is equal to the write-back register value “0011_{B}” as illustrated with the arrow 32.

Also, ninth to twelfth bits from the left of the decode ID[3:0][31:0] are “1111_{H}”, and the corresponding bits of the SFR_ID[2:0][31:0] are also “1111_{H}”. Therefore, as illustrated with a dotted arrow 33, the PWDATA “0110_{B}” is equal to the write-back register value “0110_{B}”. Similarly, second to fourth bits from the right of the decode ID[3:0][31:0] are “111_{H}”, and second to fourth bits from the right of the SFR_ID[2:0][31:0] are also “111_{H}”. Therefore, as illustrated with a dotted arrow 34, the PWDATA “110_{B}” is equal to the write-back register value “100_{B}”.

Into the write-back register value of the bit not satisfying the condition, the masking/merging circuit 130 writes the write-destination register value of this bit. For example, fifth to eighth bits from the left of the decode ID[3:0][31:0] are “1111_{H}”, and the corresponding bits of the SFR_ID[2:0][31:0] are “2222_{H}”, and therefore, they are not equal to each other. Therefore, as illustrated with a dotted arrow 35, the write-destination register value “0000_{B}” and the write-back register value “0000_{B}” are equal to each other. Similarly, the first bit from the right of the decode ID[3:0][31:0] is “0_{H}”, and the first bit from the right of the SFR_ID[2:0][31:0] is “1_{H}”, and therefore, they are not equal to each other. Therefore, as illustrated with a dotted arrow 36, the write-destination register value “0” and the write-back register value “0” are equal to each other.

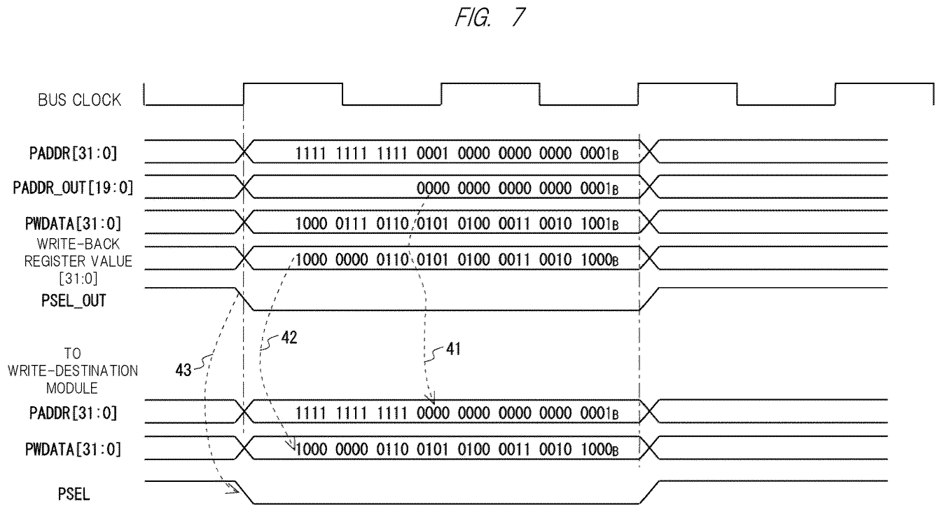

FIG. 7 is a time chart showing an operation of the write-back circuit 140. The decoder circuit 110 has already generated PADDR_OUT[15:0] from which the bit related to the write-source processor 200 has been removed. As illustrated with a dotted arrow 41, the write-back circuit 140 generates PADDR[31:0] that is combination of PADDR_OUT[19:0] based on PADDR_OUT[15:0] and PADDR[31:20], and outputs the PADDR[31:0] to the write-destination module 300. Also, as illustrated with a dotted arrow 42, the write-back circuit 140 outputs the write-back register value [31:0] as PWDATA[31:0] to the write-destination module 300. Also, as illustrated with a dotted arrow 43, the write-back circuit 140 generates PSEL based on the PSEL_OUT, and outputs the PSEL to the write-destination module 300.

The semiconductor device 100 according to the first embodiment can control the writing from the plurality of processors into the write-destination module 300 by identifying the write-source processor 200 and using the write-enable setting. This case does not need the exclusive control using the software and the register reading for the write back.

In the semiconductor device 100, the access time from the CPU can be reduced while the complication of the software is prevented. And, even if the software is modified, the function of avoiding a series of failures can be maintained.

### Second Embodiment

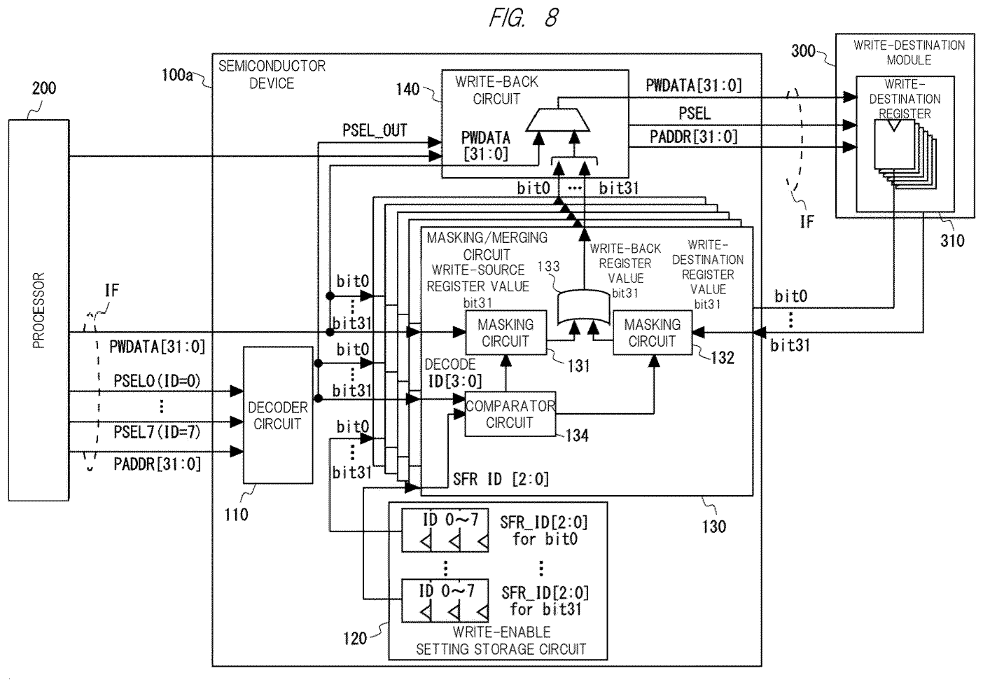

A second embodiment is a modification example of the first embodiment. With reference to FIG. 8, a configuration of a semiconductor device 100a according to the second embodiment will be explained. In comparison between FIGS. 1 and 8, PSEL (privilege) indicating that the write-source processor 200 is privileged is output to the write-back circuit 140. If the write-source processor 200 is privileged, the semiconductor device 100a outputs PADDR[31:0] and PWDATA[31:0] to the write-destination module 300 without through the masking/merging circuit 130.

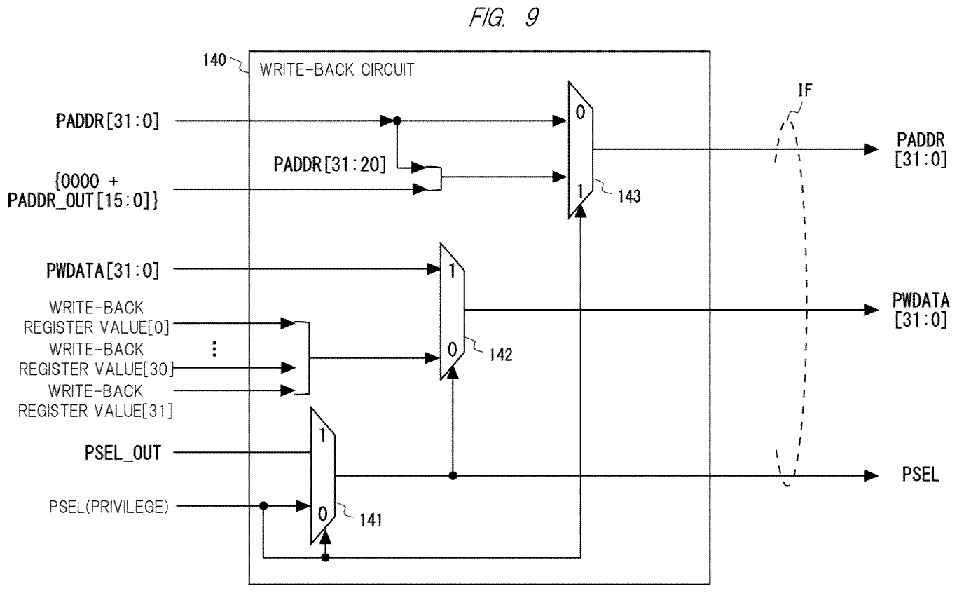

With reference to FIG. 9, the detailed configuration of the write-back circuit 140 according to the second embodiment will be explained. The write-back circuit 140 includes selectors 141 to 143.

If the PSEL (privilege) is active, the selector 141 selects the PSEL (privilege), and outputs the privilege to the write-destination module 300. If the PSEL (privilege) is active, the selector 142 selects PWDATA[31:0], and outputs PWDATA[31:0] to the write-destination module 300. If the PSEL (privilege) is active, the selector 143 selects PADDR[31:0], and outputs PADDR[31:0] to the write-destination module 300.

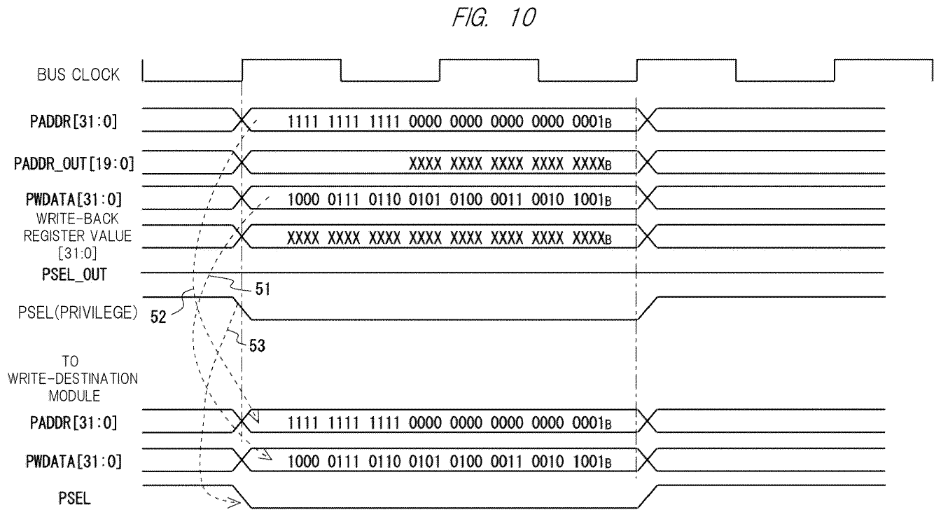

FIG. 10 is a time chart showing an operation of the write-back circuit 140 according to the second embodiment. If the PSEL (privilege) is active, as illustrated with a dotted arrow 51, not the write-back register value [31:0] but the PWDATA[31:0] is output to the write-destination module 300. Also, as illustrated with a dotted arrow 52, the PADDR[31:0] is output the write-destination module 300. Further, as illustrated with a dotted arrow 53, the PSEL (privilege) is output to the write-destination module 300.

The semiconductor device 100a according to the second embodiment can give the privilege mode of not executing the masking process to the write-source CPU, and therefore, can systematically control the access authority to the register.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a decoder circuit determining a write-source processor;
a write-enable setting storage circuit storing a write-enable setting that indicates a processor enabled to execute writing into each bit of a write-destination register;
a masking/merging circuit generating a value to be written back into the write-destination register on the basis of the write-enable setting and the write-source processor; and
a write-back circuit writing back the value to be written back into the write-destination register.

2. The semiconductor device according to claim 1,
wherein the decoder circuit receives a bus address and a bus slave selecting signal corresponding to the write-source processor as an input,
the bus address includes a bit indicating the write-source processor, and
the decoder circuit determines whether the bit included in the bus address and the bus slave selecting signal are equal to each other.

3. The semiconductor device according to claim 1,
wherein, if a masking process on each bit of the write-destination register is invalid, the decoder circuit replaces the bit with a predetermined bit to generate a decode signal, or
if the masking process on the bit is valid, the decoder circuit replaces the bit with a bit indicating the write-source processor to generate the decode signal.

4. The semiconductor device according to claim 3,
wherein, if a condition in which the bit is equal to the predetermined bit or in which the bit indicating the write-source processor is equal to the write-enable setting is satisfied, the masking/merging circuit generates the value to be written back, on the basis of write data supplied from the write-source processor, or
if the condition is not satisfied, the masking/merging circuit generates the value to be written back, on the basis of data written in the write-destination register.

5. The semiconductor device according to claim 1,
wherein, if the write-source processor is privileged, a bus address and write data are output without through the masking/merging circuit.

6. A write method comprising steps of:
determining a write-source processor;
generating a value to be written back into a write-destination register on the basis of the write-source processor and a write-enable setting that indicates a processor enabled to execute writing into each bit of the write-destination register; and
writing back the value to be written back into the write-destination register.

7. The write method according to claim 6,
wherein, if the write-source processor is privileged, a bus address and write data are output without through the step of generating the value to be written back.
